(19) United States
(12) Patent Application Publication
(10) Pub. No.: US 2025/0167034 A1
(43) Pub. Date: May 22, 2025

(54) INTEGRATED DICING/DIE BONDING FILM, METHOD FOR PRODUCING SAME, AND METHOD FOR PRODUCING SEMICONDUCTOR DEVICE

(71) Applicant: Resonac Corporation, Minato-ku, Tokyo (JP)

(72) Inventors: Takahiro KURODA, Minato-ku, Tokyo (JP); Kei ITAGAKI, Minato-ku, Tokyo (JP); Kohei TANIGUCHI, Minato-ku, Tokyo (JP); Kenya MORIYA, Minato-ku, Tokyo (JP)

(21) Appl. No.: 18/727,105

(22) PCT Filed: Dec. 20, 2022
(86) PCT No.: PCT/JP2022/046952

§ 371 Date: Feb. 12, 2025

(30) Foreign Application Priority Data
Jan. 11, 2022 (JP) 2022-002313

(51) Int. Cl. H01L 21/683; B32B 7/12; B32B 27/08; B32B 27/36; B32B 37/12; C09J 5/06; C09J 7/35; C09J 7/38; C09J 9/02; H01L 21/78

(52) U.S. Cl. CPC H01L 21/6836; B32B 7/12; B32B 27/08; B32B 27/36; B32B 37/12; C09J 5/06; C09J 7/35; C09J 7/38; C09J 9/02; H01L 21/78; B32B 2250/02; B32B 2250/244; B32B 2255/10; B32B 2255/26; B32B 2264/1051; B32B 2264/302; B32B 2264/303; B32B 2307/202; B32B 2307/54; B32B 2307/748; B32B 2367/00; B32B 2405/00; C09J 2203/326; C09J 2301/204; C09J 2301/208; C09J 2301/302; C09J 2301/304; C09J 2301/314; C09J 2301/408

(57) ABSTRACT

An Integrated dicing/die bonding film is disclosed. This integrated dicing/die bonding film includes, in the stated order: a first base material layer; a die-bonding film containing electroconductive particles; a pressure-sensitive adhesive layer; and a second base material layer. The first base material layer has a cut portion provided on a surface of the die-bonding film side along an outer edge of the die-bonding film. A maximum value of 30° peeling strength of the die-bonding film with respect to the first base material layer as measured at 25° C. is 0.50 N/20 mm or less.

### TECHNICAL FIELD

The present disclosure relates to an integrated dicing/die bonding film, a method for producing the same, and a method for producing a semiconductor device.

### BACKGROUND ART

Conventionally, a semiconductor device is produced through the following steps. First, a semiconductor wafer is pasted to a pressure-sensitive adhesive sheet for dicing, and in this state, the semiconductor wafer is singulated into semiconductor chips (dicing step). Thereafter, a pickup step, a pressure bonding step, a die bonding step, and the like are performed. Patent Literature 1 discloses a pressure-sensitive adhesive film (integrated dicing/die bonding film) having both a function of fixing a semiconductor wafer in a dicing step and a function of bonding a semiconductor chip to a substrate in a die bonding step. In the dicing step, the semiconductor wafer and the die-bonding film are singulated so that die-bonding film piece-attached semiconductor chips can be obtained.

In recent years, devices called power semiconductor devices that perform control of electric power and the like have been popularized. Power semiconductor devices are likely to generate heat due to the electric current supplied thereto and are required to have excellent heat dissipation properties. Patent Literature 2 discloses a die-bonding film-attached dicing tape (integrated dicing/die bonding film) including a die-bonding film having higher heat dissipation properties after curing compared with the heat dissipation properties before curing.

### CITATION LIST

### Patent Literature

Patent Literature 1: JP 2008-218571 A
Patent Literature 2: JP 2016-103524 A

### SUMMARY OF INVENTION

### Technical Problem

In the process of developing a semiconductor device having excellent heat dissipation properties, the present inventors blended an amount of electroconductive particles sufficient to obtain sufficient heat dissipation properties into a die-bonding film of an integrated dicing/die bonding film including, in the stated order, a first base material layer, a die-bonding film, a pressure-sensitive adhesive layer, and a second base material layer. The present inventors have studied sticking such an integrated dicing/die bonding film to a semiconductor wafer (wafer lamination step), and have found that there are cases where defects occur, for example, the first base material layer and the die-bonding film of the integrated dicing/die bonding film cannot be peeled from each other, the die-bonding film is pulled by the first base material layer to be torn off, and even when these members can be peeled midway, the die-bonding film is in a stretched state and cannot be mounted on the semiconductor wafer. According to further studies of the present inventors, it has been found that such defects tend to occur more easily in a case where the electroconductive particles are blended into the die-bonding film than in a case where the electroconductive particles are not blended into the die-bonding film.

Therefore, a main object of the present disclosure is to provide an integrated dicing/die bonding film capable of suppressing occurrence of defects in a wafer lamination step and a method for producing the same, the integrated dicing/die bonding film including, in the stated order, a first base material layer, a die-bonding film containing electroconductive particles, a pressure-sensitive adhesive layer, and a second base material layer.

### Solution to Problem

In the production of an integrated dicing/die bonding film, usually, a first laminate including a first base material layer and an original sheet of a die-bonding film provided on the first base material layer undergoes producing a second laminate including a first base material layer and a die-bonding film provided on the first base material layer by die cutting the original sheet of the die-bonding film in the first laminate so as to form a cut portion on a surface of the first base material layer. According to studies of the present inventors, it has been found that in a case where the original sheet of the die-bonding film contains electroconductive particles, since the electroconductive particles are soft, the electroconductive particles are crushed and, at the same time, stick to a side surface of the cut portion at the time of die cutting, which makes it difficult to peel the first base material layer and the die-bonding film from each other. According to further studies of the present inventors, it has been found that by adjusting a maximum value of 30° peeling strength of the die-bonding film with respect to the first base material layer to a predetermined range, occurrence of defects when the integrated dicing/die bonding film is stuck to the semiconductor wafer (occurrence of defects in the wafer lamination step) can be suppressed, thereby completing the invention of the present disclosure.

An aspect of the present disclosure relates to an integrated dicing/die bonding film. This integrated dicing/die bonding film includes, in the stated order: a first base material layer; a die-bonding film containing electroconductive particles; a pressure-sensitive adhesive layer; and a second base material layer. The first base material layer has a cut portion provided on a surface of the die-bonding film side along an outer edge of the die-bonding film. A maximum value of 30° peeling strength of the die-bonding film with respect to the first base material layer as measured at 25° C. is 0.50 N/20 mm or less.

The die-bonding film may further contain a thermosetting resin, a curing agent, and an elastomer. A content of the electroconductive particles may be 70.0% by mass or more based on the total amount of the die-bonding film.

An average particle size of the electroconductive particles may be 0.01 to 10 μm. The electroconductive particles may be silver particles.

Another aspect of the present disclosure relates to a method for producing the above-described integrated dicing/die bonding film. The method for producing the integrated dicing/die bonding film includes: preparing a first laminate including the first base material layer and an original sheet of the die-bonding film provided on the first base material layer; producing a second laminate including the first base material layer and the die-bonding film provided on the first base material layer by die cutting the original sheet of the die-bonding film in the first laminate so as to form the cut portion on a surface of the first base material layer; and laminating the pressure-sensitive adhesive layer and the second base material layer in this order on the die-bonding film in the second laminate.

Still another aspect of the present disclosure relates to a method for producing a semiconductor device. This method for producing a semiconductor device includes: peeling the first base material layer of the above-described integrated dicing/die bonding film and sticking the die-bonding film of the integrated dicing/die bonding film to a semiconductor wafer; producing a plurality of singulated die-bonding film piece-attached semiconductor chips by dicing the semiconductor wafer with the die-bonding film stuck thereto; and bonding the die-bonding film piece-attached semiconductor chips to a support member with a die-bonding film piece interposed therebetween.

### Advantageous Effects of Invention

According to the present disclosure, there are provided an integrated dicing/die bonding film capable of suppressing occurrence of defects in a wafer lamination step and a method for producing the same, the integrated dicing/die bonding film including, in the stated order, a first base material layer; a die-bonding film containing electroconductive particles; a pressure-sensitive adhesive layer; and a second base material layer. Furthermore, according to the present disclosure, there is provided a method for producing a semiconductor device using an integrated dicing/die bonding film.

The present disclosure provides an integrated dicing/die bonding film described in [1] to [4], a method for producing an integrated dicing/die bonding film described in [5], and a method for producing a semiconductor device described in [6].

[1] An integrated dicing/die bonding film including, in the stated order: a first base material layer; a die-bonding film containing electroconductive particles; a pressure-sensitive adhesive layer; and a second base material layer, in which the first base material layer has a cut portion provided on a surface of the die-bonding film side along an outer edge of the die-bonding film, and a maximum value of 30° peeling strength of the die-bonding film with respect to the first base material layer as measured at 25° C. is 0.50 N/20 mm or less.

[2] The Integrated dicing/die bonding film described in [1], in which the die-bonding film further contains a thermosetting resin, a curing agent, and an elastomer, and a content of the electroconductive particles is 70.0% by mass or more based on the total amount of the die-bonding film.

[3] The integrated dicing/die bonding film described in [1] or [2], in which an average particle size of the electroconductive particles is 0.01 to 10 μm.

[4] The integrated dicing/die bonding film described in any one of [1] to [3], in which the electroconductive particles are silver particles.

[5] A method for producing the integrated dicing/die bonding film described in any one of [1] to [4], the method including: preparing a first laminate including the first base material layer and an original sheet of the die-bonding film provided on the first base material layer; producing a second laminate including the first base material layer and the die-bonding film provided on the first base material layer by die cutting the original sheet of the die-bonding film in the first laminate so as to form the cut portion on a surface of the first base material layer; and laminating the pressure-sensitive layer and the second base material layer in this order on the die-bonding film in the second laminate.

[6] A method for producing a semiconductor device, the method including: peeling the first base material layer of the integrated dicing/die bonding film described in any one of [1] to [4] and sticking the die-bonding film of the integrated dicing/die bonding film to a semiconductor wafer; producing a plurality of singulated die-bonding film piece-attached semiconductor chips by dicing the semiconductor wafer with the die-bonding film stuck thereto; bonding the die-bonding film piece-attached semiconductor chips to a support member with a die-bonding film piece interposed therebetween; and thermally curing the die-bonding film piece in the die-bonding film piece-attached semiconductor chips bonded to the support member.

### BRIEF DESCRIPTION OF DRAWINGS

FIG. 1(a) is a plan view schematically illustrating an embodiment of an integrated dicing/die bonding film, and FIG. 1(b) is a cross-sectional view taken along line b-b of FIG. 1(a).

FIGS. 2(a), 2(b), and 2(c) are cross-sectional views schematically illustrating production processes of the integrated dicing/die bonding film.

FIGS. 3(a) and 3(b) are cross-sectional views schematically illustrating production processes of the integrated dicing/die bonding film.

FIGS. 4(a) and 4(b) are cross-sectional views schematically illustrating respective steps of a method for producing a semiconductor device.

FIGS. 5(a) and 5(b) are cross-sectional views schematically illustrating respective steps of a method for producing a semiconductor device.

FIGS. 6(a), 6(b), and 6(c) are cross-sectional views schematically illustrating respective steps of a method for producing a semiconductor device.

FIG. 7 is a schematic cross-sectional view illustrating an embodiment of a semiconductor device.

### DESCRIPTION OF EMBODIMENTS

Hereinafter, embodiments of the present disclosure will be described with reference to the drawings as appropriate. However, the present disclosure is not limited to the following embodiments. In the following embodiments, the constituent elements (including a step or the like) are not always indispensable unless otherwise specified. The sizes of constituent elements in the respective drawings are conceptual, and the relative size relationships between the constituent elements are not restricted to those illustrated in the respective drawings.

The same applies to numerical values and ranges thereof in the present disclosure, and does not limit the present disclosure. In the present specification, a numerical range that has been indicated by use of “to” indicates the range that includes the numerical values which are described before and after “to”, as the minimum value and the maximum value, respectively. In the numerical ranges that are described stepwise in the present specification, the upper limit value or the lower limit value described in a numerical range may be replaced with the upper limit value or the lower limit value in another numerical range that is described stepwise. Furthermore, in a numerical range described in the present specification, the upper limit value or the lower limit value of the numerical range may be replaced with a value shown in the Examples.

In the present specification, the term “layer” encompasses a structure of a shape thereof formed all over a surface seen as a plan view and also a structure of a shape thereof partially formed. Furthermore, in the present specification, the term “step” includes not only an independent step but also a step by which an intended action of the step is achieved, even though the step cannot be clearly distinguished from other steps.

In the present specification, (meth)acrylate means acrylate or methacrylate corresponding thereto. The same applies to other analogous expressions such as a (meth)acryloyl group and a (meth)acrylic copolymer.

Each of components and materials exemplified in the present specification may be used singly or may be used in combination of two or more kinds thereof, unless otherwise specified.

### [Integrated Dicing/Die Bonding Film]

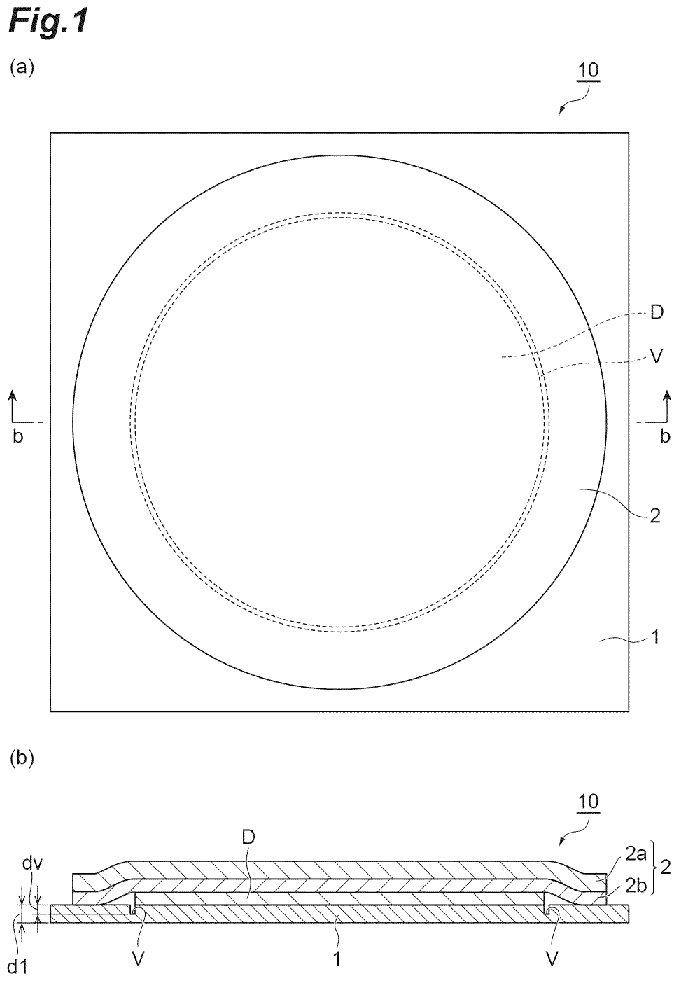

FIG. 1(a) is a plan view schematically illustrating an embodiment of an integrated dicing/die bonding film, and FIG. 1(b) is a cross-sectional view taken along line b-b of FIG. 1(a). An integrated dicing/die bonding film 10 (hereinafter, simply referred to as “integrated film 10” in some cases) includes, in the stated order, a first base material layer 1, a die-bonding film D, a pressure-sensitive adhesive layer 2b, and a second base material layer 2a. Note that, the die-bonding film means a film used for bonding a semiconductor chip and a support member or bonding semiconductor chips to each other. Furthermore, a laminated film having the second base material layer 2a and the pressure-sensitive adhesive layer 2b provided on the second base material layer 2a is referred to as “dicing film 2” in some cases.

The first base material layer 1 is not particularly limited, and examples thereof include plastic films of polytetrafluoroethylene, polyethylene, polypropylene, polymethylpentene, polyethylene terephthalate (PET), and polyimide. These plastic films may be subjected to a mold release treatment. The first base material layer 1 may be, for example, a polyethylene terephthalate (PET) film.

A thickness d1 of the first base material layer 1 may be, for example, 10 μm or more, 20 μm or more, or 30 μm or more, from the viewpoint of further easily peeling the first base material layer 1 and the die-bonding film D in a wafer lamination step. The thickness d1 of the first base material layer 1 may be 100 μm or less, 80 μm or less, or 60 μm or less, from the viewpoint of suppressing an increase in warpage due to heat in a coating step, a wafer lamination step, and the like of the die-bonding film.

The first base material layer 1 has a cut portion V (first cut portion) provided on a surface of the die-bonding film D side along an outer edge of the die-bonding film D. As described below, the cut portion is formed on the surface of the die-bonding film D side of the first base material layer 1 at the time of die cutting an original sheet of the die-bonding film, for example, by a punching blade, or the like. The shape of the cut portion V in cross-sectional view may be, for example, approximately rectangular (square or oblong) as illustrated in FIG. 1(b), or may be approximately triangular.

A ratio of a depth dv of the cut portion V (first cut portion) with respect to the thickness d1 of the first base material layer 1 may be 50% or less, 45% or less, or 40% or less. When this ratio is in such a range, a maximum value of 30° peeling strength of the die-bonding film D with respect to the first base material layer 1 is easily adjusted to a predetermined range, and as a result, occurrence of defects in the wafer lamination step can be even more suppressed. This ratio may be, for example, 20% or more, 25% or more, or 30% or more. Note that, the depth dv of the cut portion V is measured by cross-sectional observation with an electron microscope.

The die-bonding film D is composed of a die-bonding film obtained by die cutting the original sheet of the die-bonding film. The die-bonding film D contains electroconductive particles (hereinafter, referred to as “component (A)” in some cases). The die-bonding film may further contain a thermosetting resin (hereinafter, referred to as “component (B)” in some cases), a curing agent (hereinafter, referred to as “component (C)” in some cases), and an elastomer (hereinafter, referred to as “component (D)” in some cases). The die-bonding film D may further contain a coupling agent (hereinafter, referred to as “component (E)” in some cases), a curing accelerator (hereinafter, referred to as “component (F)” in some cases), and the like.

The die-bonding film D may be in a cured product (C-stage) state through a semi-cured (B-stage) state in which at least a part of the die-bonding film D is cured and then a heating treatment.

### Component (A): Electroconductive Particles

The electroconductive particles as the component (A) are a component for enhancing heat dissipation properties when the die-bonding film is applied to a semiconductor device.

Examples of the component (A) include particles including metals such as aluminum, nickel, tin, bismuth, indium, zinc, iron, copper, silver, gold, palladium, and platinum. The component (A) may be electroconductive particles composed of one kind of metal, or may be electroconductive particles composed of two or more kinds of metals. The electroconductive particles composed of two or more kinds of metals may be metal-coated electroconductive particles in which the surface of electroconductive particles is coated with a metal different from the electroconductive particles.

The component (A) may be, for example, electroconductive particles composed of a metal having an electrical conductivity (0° C.) of 40×10⁶ S/m or more. By using such a component (A), heat dissipation properties can be even more improved. Examples of the metal having an electrical conductivity (0° C.) of 40×10⁶ S/m or more include gold (49×10⁶ S/m), silver (67×10⁶ S/m), and copper (65×10⁶ S/m). The electrical conductivity (0° C.) may be 45×10⁶ S/m or more or 50×10⁶ S/m or more. That is, the component (A) is preferably electroconductive particles composed of silver and/or copper.

The component (A) may be, for example, electroconductive particles composed of a metal having a thermal conductivity (20° C.) of 250 W/m·K or more. By using such a component (A), heat dissipation properties can be even more improved. Examples of the metal having a thermal conductivity (20° C.) of 250 W/m·K or more include gold (295 W/m·K), silver (418 W/m·K), and copper (372 W/m·K). The thermal conductivity (20° C.) may be 300 W/m·K or more or 350 W/m·K or more. That is, the component (A) is preferably electroconductive particles composed of silver and/or copper.

The component (A) may be silver particles from the viewpoint of being excellent in terms of the electrical conductivity and the thermal conductivity and being less likely to be oxidized. The silver particles may be, for example, particles composed of silver (particles composed of silver alone) or silver-coated metal particles in which the surface of metal particles (copper particles or the like) is coated with silver. Examples of the silver-coated electroconductive particles include silver-coated copper particles. The component (A) may be particles composed of silver.

The silver particles as the component (A) are not particularly limited, and examples thereof include silver particles produced by a reduction method (silver particles produced by a liquid phase (wet type) reduction method using a reducing agent), and silver particles produced by an atomization method. The silver particles as the component (A) may be silver particles produced by a reduction method.

In the liquid phase (wet type) reduction method using a reducing agent, a surface treatment agent (lubricant) is usually added from the viewpoint of controlling the particle size and preventing aggregation and fusion, and silver particles produced by a liquid phase (wet type) reduction method using a reducing agent have a surface coated with a surface treatment agent (lubricant). Therefore, silver particles produced by a reduction method can also be considered as silver particles surface-treated with a surface treatment agent. Examples of the surface treatment agent include fatty acid compounds such as oleic acid (melting point: 13.4° C.), myristic acid (melting point: 54.4° C.), palmitic acid (melting point: 62.9° C.), and stearic acid (melting point: 69.9° C.), fatty acid amide compounds such as oleic acid amide (melting point: 76° C.) and stearic acid amide (melting point: 100° C.), aliphatic alcohol compounds such as pentanol (melting point: −78° C.), hexanol (melting point: −51.6° C.), oleyl alcohol (melting point: 16° C.), and stearyl alcohol (melting point: 59.4° C.), and aliphatic nitrile compounds such as oleanitrile (melting point: −1° C.). The surface treatment agent may be a surface treatment agent having a low melting point (for example, a melting point of 100° C. or lower) and high solubility in an organic solvent.

The shape of the component (A) is not particularly limited, and may be, for example, a flake shape, a resin shape, a spherical shape, or the like and may be a spherical shape. When the shape of the component (A) is a spherical shape, there is a tendency that the surface roughness (Ra) of the die-bonding film is easily improved.

The average particle size of the component (A) may be 0.01 to 10 μm. When the average particle size of the component (A) is 0.01 μm or more, there is a tendency that effects of capable of preventing an increase in viscosity at the time of producing an adhesive varnish, capable of incorporating a desired amount of the component (A) into the die-bonding film, capable of exhibiting more favorable adhesiveness by securing the wettability of the die-bonding film to an adherend, and the like. When the average particle size of the component (A) is 10 μm or less, there is a tendency that the film molding properties are more excellent, and the heat dissipation properties brought by addition of the component (A) can be further improved. Furthermore, when the average particle size of the component (A) is 10 μm or less, the thickness of the die-bonding film can be made thinner, semiconductor chips can be more highly laminated, and at the same time, the generation of cracks in semiconductor chips caused by protrusion of the component (A) from the die-bonding film can be prevented. The average particle size of the component (A) may be 0.1 μm or more, 0.3 μm or more, or 0.5 μm or more, or may be 8.0 μm or less, 7.0 μm or less, 6.0 μm or less, 5.0 μm or less, 4.0 μm or less, or 3.0 μm or less.

Note that, in the present specification, the average particle size of the component (A) means the particle size (laser 50% particle size (D₅₀)) when the ratio (volume fraction) with respect to the volume of the entire component (A) is 50%. The average particle size (D₅₀) can be determined by measuring a suspension obtained by suspending the component (A) in water by a laser scattering method using a laser scattering type particle size measurement apparatus (for example, MicroTrac).

The content of the component (A) may be 70.0% by mass or more, or may be 71.0% by mass or more, 72.0% by mass or more, 73.0% by mass or more, 74.0% by mass or more, 74.5% by mass or more, 75.0% by mass or more, or 75.5% by mass or more, based on the total amount of the die-bonding film. When the content of the component (A) is 70.0% by mass or more based on the total amount of the die-bonding film, there is a tendency that the thermal conductivity of the die-bonding film is improved, and the heat dissipation properties of the semiconductor device can be further improved. The content of the component (A) may be, for example, 85.0% by mass or less, 82.0% by mass or less, 81.0% by mass or less, or 80.0% by mass or less, based on the total amount of the die-bonding film. When the content of the component (A) is 85.0% by mass or less based on the total amount of the die-bonding film, other components can be contained more sufficiently in the die-bonding film. Thereby, physical properties such as shear viscosity and storage elastic modulus of the die-bonding film are easily adjusted to predetermined ranges, and for example, the step embeddability of the die-bonding film can be improved.

The content of the component (A) may be 20.0% by volume or more, or may be 21.0% by volume or more, 22.0% by volume or more, 22.5% by volume or more, 23.0% by volume or more, 23.5% by volume or more, 24.0% by volume or more, 24.5% by volume or more, 24.8% by volume or more, or 25.0% by volume or more, based on the total amount of the die-bonding film. When the content of the component (A) is 20.0% by volume or more based on the total amount of the die-bonding film, there is a tendency that the thermal conductivity of the die-bonding film is improved, and the heat dissipation properties of the semiconductor device can be further improved. The content of the component (A) may be, for example, 33.0% by volume or less, 31.0% by volume or less, 30.0% by volume or less, or 29.0% by volume or less, based on the total amount of the die-bonding film. When the content of the component (A) is 33.0% by volume or less based on the total amount of the die-bonding film, other components can be contained more sufficiently in the die-bonding film. Thereby, physical properties such as shear viscosity and storage elastic modulus of the die-bonding film are easily adjusted to predetermined ranges, and for example, the step embeddability of the die-bonding film can be improved.

The content (% by volume) of the component (A) can be calculated, for example, from Formula (I) below when the density of the die-bonding film is designated as x (g/cm³), the density of the component (A) is designated as y (g/cm³), and the mass proportion of the component (A) in the die-bonding film is designated as z (% by mass). Note that, the mass proportion of the component (A) in the die-bonding film can be determined, for example, by thermogravimetric analysis using a thermogravimetric differential thermal analyzer (TG-DTA). Furthermore, the density of the die-bonding film and the density of the component (A) can be determined by measuring the mass and the specific gravity using a specific gravity meter.

$$Content ( \% by volume ) of Component ( A ) = ( x / y ) \times z \qquad ( I )$$

Measurement conditions of TG-DTA: temperature range of 30 to 600° C. (temperature increase rate: 30° C./min), maintained at 600° C. for 20 minutes
Air flow rate: 300 mL/min
Thermogravimetric differential thermal analyzer: TG/DTA220 manufactured by Seiko Instruments Inc.
Specific gravity meter: EW-300SG manufactured by Alfa Mirage Co., Ltd.

### Component (B): Thermosetting Resin

The component (B) is a component having a property of forming a three-dimensional bond between molecules and being cured by heating or the like, and is a component exhibiting an adhesive action after being curing. The component (B) may be an epoxy resin. The epoxy resin can be used without particular limitation as long as it has an epoxy group in the molecule. The epoxy resin may have two or more epoxy groups in the molecule.

Examples of the epoxy resin include a bisphenol A type epoxy resin, a bisphenol F type epoxy resin, a bisphenol S type epoxy resin, a phenol novolac type epoxy resin, a cresol novolac type epoxy resin, a bisphenol A novolac type epoxy resin, a bisphenol F novolac type epoxy resin, a stilbene type epoxy resin, a triazine skeleton-containing epoxy resin, a fluorene skeleton-containing epoxy resin, a triphenolmethane type epoxy resin, a biphenyl type epoxy resin, a xylylene type epoxy resin, a biphenyl aralkyl type epoxy resin, a naphthalene type epoxy resin, a dicyclopentadiene type epoxy resin, a diglycidyl ether compound of a polyfunctional phenol and a polycyclic aromatic compound, such as anthracene.

The epoxy resin may include an epoxy resin having a softening point of 50° C. or higher. When the epoxy resin includes such an epoxy resin, there is a tendency that the maximum value of 30° peeling strength of the die-bonding film with respect to the first base material layer is easily adjusted to a predetermined range.

Note that, in the present specification, the softening point means a value as measured by a ring and ball method in accordance with JIS K7234.

The epoxy equivalent of the epoxy resin is not particularly limited, and may be 90 to 300 g/eq or 110 to 290 g/eq. When the epoxy equivalent of the epoxy resin is in such a range, there is a tendency that the fluidity of the adhesive varnish when the die-bonding film is formed is easily secured while the bulk strength of the die-bonding film is maintained.

The content of the component (B) may be 1.0% by mass or more, 3.0% by mass or more, 5.0% by mass or more, or 7.0% by mass or more, or may be 15.0% by mass or less, 14.0% by mass or less, 13.0% by mass or less, 12.0% by mass or less, or 11.0% by mass or less, based on the total amount of the die-bonding film.

### Component (C): Curing Agent

The component (C) is a component acting as a curing agent of the component (B). In a case where the component (B) is an epoxy resin, the component (C) may be an epoxy resin curing agent. Examples of the component (C) include a phenolic resin (phenol-based curing agent), an acid anhydride-based curing agent, an amine-based curing agent, an imidazole-based curing agent, a phosphine-based curing agent, an azo compound, and an organic peroxide. In a case where the component (B) is an epoxy resin, the component (C) may be a phenolic resin from the viewpoint of handling property, storage stability, and curability.

The phenolic resin can be used without particular limitation as long as it has a phenolic hydroxyl group in the molecule. Examples of the phenolic resin include novolac type phenolic resins obtained by condensation or co-condensation of phenols such as phenol, cresol, resorcin, catechol, bisphenol A, bisphenol F, phenylphenol, and aminophenol and/or naphthols such as α-naphthol, β-naphthol, and dihydroxynaphthalene with a compound having an aldehyde group such as formaldehyde in the presence of an acidic catalyst; and phenol aralkyl resins and naphthol aralkyl resins synthesized from phenols such as allylated bisphenol A, allylated bisphenol F, allylated naphthalene diol, phenol novolac, phenol and/or naphthols with dimethoxyparaxylene or bis(methoxymethyl) biphenyl, a biphenyl aralkyl type phenolic resin, and a phenyl aralkyl type phenolic resin.

The phenolic resin may include a phenolic resin having a softening point of 90° C. or lower. When the phenolic resin includes a phenolic resin having a softening point of 90° C. or lower, since the phenolic resin is sufficiently liquefied at 110° C., there is a tendency that physical properties such as shear viscosity and storage elastic modulus of the die-bonding film are easily adjusted to predetermined ranges.

The hydroxyl equivalent of the phenolic resin may be 40 to 300 g/eq, 70 to 290 g/eq, or 100 to 280 g/eq. When the hydroxyl equivalent of the phenolic resin is 40 g/eq or more, there is a tendency that the storage elastic modulus of the die-bonding film is further improved, and when the hydroxyl equivalent thereof is 300 g/eq or less, defects caused by generation of foam, outgas, or the like can be prevented.

A ratio of the epoxy equivalent of the epoxy resin as the component (B) and the hydroxyl equivalent of the phenolic resin as the component (C) (the epoxy equivalent of the epoxy resin as the component (B)/the hydroxyl equivalent of the phenolic resin as the component (C)) may be 0.30/0.70 to 0.70/0.30, 0.35/0.65 to 0.65/0.35, 0.40/0.60 to 0.60/0.40, or 0.45/0.55 to 0.55/0.45, from the viewpoint of curability. When this equivalent ratio is 0.30/0.70 or more, there is a tendency that more sufficient curability is obtained. When this equivalent ratio is 0.70/0.30 or less, an excessive increase in viscosity can be prevented and more sufficient fluidity can be obtained.

The content of the component (C) may be 1.0% by mass or more, 3.0% by mass or more, 4.0% by mass or more, or 5.0% by mass or more, or may be 15.0% by mass or less, 12.0% by mass or less, 10.0% by mass or less, or 9.0% by mass or less, based on the total amount of the die-bonding film.

The total content of the component (B) and the component (C) may be 13.0% by mass or more based on the total amount of the die-bonding film. When the total content of the component (B) and the component (C) is 13.0% by mass or more based on the total amount of the die-bonding film, physical properties such as shear viscosity and storage elastic modulus of the die-bonding film are easily adjusted to predetermined ranges, and for example, the step embeddability of the die-bonding film can be improved. The total content of the component (B) and the component (C) may be 13.2% by mass or more, 13.5% by mass or more, 14.0% by mass or more, 14.5% by mass or more, 15.0% by mass or more, or 15.5% by mass or more, based on the total amount of the die-bonding film. The total content of the component (B) and the component (C) may be 30.0% by mass or less, 25.0% by mass or less, 23.0% by mass or less, 22.0% by mass or less, 21.0% by mass or less, 20.0% by mass or less, or 18.0% by mass or less, based on the total amount of the die-bonding film.

### Component (D): Elastomer

Examples of the component (D) include a polyimide resin, an acrylic resin, a urethane resin, a polyphenylene ether resin, a polyether imide resin, a phenoxy resin, and a modified polyphenylene ether resin. The component (D) may be one of these resins while being a resin having a cross-linkable functional group or may be an acrylic resin having a cross-linkable functional group. Here, the acrylic resin means a (meth)acrylic (co) polymer including a structural unit derived from (meth)acrylate ((meth)acrylic acid ester). The acrylic resin may be a (meth)acrylic (co) polymer including a structural unit derived from a (meth)acrylate having a cross-linkable functional group such as an epoxy group, an alcoholic or phenolic hydroxyl group, or a carboxy group. Furthermore, the acrylic resin may be acrylic rubber such as a copolymer of (meth)acrylate and acrylonitrile. These elastomers may be used singly or in combination of two or more kinds thereof.

Examples of commercially available products of the acrylic resin include SG-P3, SG-70L, SG-708-6, WS-023 EK30, SG-280 EK23, HTR-860P-3, HTR-860P-3CSP, and HTR-860P-3CSP-3 DB (all manufactured by Nagase ChemteX Corporation).

The glass transition temperature (Tg) of the elastomer as the component (D) may be −50 to 50° C. or −30 to 20° C. When the Tg is −50° C. or higher, there is a tendency that handling property is further improved since the tackiness of the die-bonding film is lowered. When the Tg is 50° C. or lower, there is a tendency that the fluidity of the adhesive varnish when the die-bonding film is formed can be further sufficiently secured. Herein, the Tg of the elastomer as the component (D) means a value measured using DSC (thermal differential scanning calorimeter) (for example, trade name: Thermo Plus 2 manufactured by Rigaku Corporation).

The weight average molecular weight (Mw) of the elastomer as the component (D) may be 50000 to 1600000, 100000 to 1400000, or 300000 to 1200000. When the weight average molecular weight of the elastomer as the component (D) is 50000 or more, there is a tendency that film formability is more excellent. When the weight average molecular weight of the component (D) is 1600000 or less, there is a tendency that the fluidity of the adhesive varnish when the die-bonding film is formed is further excellent. Herein, the Mw of the elastomer as the component (D) means a value as measured by gel permeation chromatography (GPC) and converted using a calibration curve of standard polystyrene.

The measurement apparatus, measurement conditions, and the like of Mw of the elastomer as the component (D) are, for example, as follows.
Pump: L-6000 (manufactured by Hitachi, Ltd.)
Column: Column in which Gelpack GL-R440 (manufactured by Showa Denko Materials Co., Ltd.), Gelpack GL-R450 (manufactured by Showa Denko Materials Co., Ltd.), and Gelpack GL-R400M (manufactured by Showa Denko Materials Co., Ltd.) (each having a size of 10.7 mm (diameter)×300 mm) are connected in this order
Eluent: Tetrahydrofuran (hereinafter, referred to as “THF”)
Sample: Solution obtained by dissolving 120 mg of a sample in 5 mL of THF
Flow rate: 1.75 mL/min

The content of the component (D) may be 15.0% by mass or less, 12.0% by mass or less, 10.0% by mass or less, or 9.0% by mass or less, based on the total amount of the die-bonding film. When the content of the component (D) is 15.0% by mass or less based on the total amount of the die-bonding film, it is possible to prevent that the viscosity becomes too high, and for example, the step embeddability is decreased. From the viewpoint of film processability, the lower limit of the content of the component (D) may be 1.0% by mass or more, 1.5% by mass or more, 2.0% by mass or more, 2.5% by mass or more, or 2.8% by mass or more, based on the total amount of the die-bonding film.

### Component (E): Coupling Agent

The component (E) may be a silane coupling agent. Examples of the silane coupling agent include γ-ureidopropyltriethoxysilane, γ-mercaptopropyltrimethoxysilane, 3-phenylaminopropyltrimethoxysilane, and 3-(2-aminoethyl)aminopropyltrimethoxysilane.

### Component (F): Curing Accelerator

Examples of the component (F) include imidazoles and derivatives thereof, an organic phosphorus-based compound, secondary amines, tertiary amines, and a quaternary ammonium salt. Of these, the component (F) may be imidazoles and derivatives thereof from the viewpoint of reactivity.

Examples of the imidazoles include 2-methylimidazole, 1-benzyl-2-methylimidazole, 1-cyanoethyl-2-phenylimidazole, and 1-cyanoethyl-2-methylimidazole. These may be used singly or in combination of two or more kinds thereof.

The die-bonding film may further contain other components. Examples of the other components include a pigment, an ion scavenger, and an antioxidant.

The total content of the component (E), the component (F), and the other components may be 0.005 to 10% by mass based on the total amount of the die-bonding film.

Another embodiment of the die-bonding film contains the component (A), the component (B), the component (C), and the component (D). Based on the total amount of the die-bonding film, the content of the component (A) is 74.5% by mass or more, and the total content of the component (B) and the component (C) is 13.0% by mass or more. In the die-bonding film of the present embodiment, the type, content, and the like of each component are the same as the type, content, and the like of each component exemplified in the above-described embodiment.

A method for producing an original sheet of the die-bonding film (or the die-bonding film) is not particularly limited, and the original sheet of the die-bonding film (or the die-bonding film) can be obtained, for example, by a production method including a step (mixing step) of mixing a raw material varnish containing the component (A) and an organic solvent to prepare an adhesive varnish containing the component (A), the organic solvent, and as necessary, the component (B) and the component (C), and a step (forming step) of forming an original sheet of the die-bonding film using the adhesive varnish. The adhesive varnish may further contain, as necessary, the component (D), the component (E), the component (F), other components, and the like.

### (Mixing Step)

The mixing step is a step of mixing a raw material varnish containing the component (A) and an organic solvent to prepare an adhesive varnish containing the component (A), the organic solvent, and as necessary, the component (B) and the component (C).

The organic solvent is not particularly limited as long as it can dissolve a component other than the component (A). Examples of the organic solvent include aromatic hydrocarbons such as toluene, xylene, mesitylene, cumene, and p-cymene; aliphatic hydrocarbons such as hexane and heptane; cyclic alkanes such as methylcyclohexane; cyclic ethers such as tetrahydrofuran and 1,4-dioxane; ketones such as acetone, methyl ethyl ketone, methyl isobutyl ketone, cyclohexanone, and 4-hydroxy-4-methyl-2-pentanone; esters such as methyl acetate, ethyl acetate, butyl acetate, methyl lactate, ethyl lactate, γ-butyrolactone, butyl carbitol acetate, and ethyl carbitol acetate; carbonic esters such as ethylene carbonate and propylene carbonate; amides such as N,N-dimethylformamide, N,N-dimethylacetamide, and N-methyl-2-pyrrolidone; and alcohols such as butyl carbitol and ethyl carbitol. These may be used singly or in combination of two or more kinds thereof. Of these, from the viewpoint of the solubility and boiling point of the surface treatment agent, the organic solvent may be N,N-dimethylformamide, N,N-dimethylacetamide, N-methyl-2-pyrrolidone, butyl carbitol, ethyl carbitol, butyl carbitol acetate, ethyl carbitol acetate, or cyclohexanone. The solid component concentration in the raw material varnish may be 10 to 80% by mass based on the total amount of the raw material varnish.

The raw material varnish can be obtained by, for example, adding at least the component (A) and the organic solvent to a container used in a stirrer. In this case, the order of addition of each component is not particularly limited, and can be appropriately set according to the properties of each component.

Mixing can be performed by appropriately combining general stirrers such as a homo-disper, a three-one motor, a mixing rotor, a planetary, and a Raikai mixer. The stirrer may include a heating facility such as a heater unit capable of managing the temperature conditions for the raw material varnish or the adhesive varnish. In a case where a homo-disper is used for mixing, the speed of rotation of the homo-disper may be 4000 rotations/min or more.

The mixing temperature of the mixing step is not particularly limited, and may be 50° C. or higher. Regarding the mixing temperature of the mixing step, heating may be performed using a heating facility or the like as necessary. According to studies of the inventors of the present disclosure, it was found that when the mixing temperature of the mixing step is 50° C. or higher, for example, in the case of using silver particles (preferably, silver particles produced by a reduction method), the original sheet of the die-bonding film to be obtained (or the die-bonding film) may include a sintered body of silver particles in the C-stage state. Such a phenomenon is exhibited more notably when silver particles produced by a reduction method are used as the component (A). The reason why such a phenomenon is exhibited is not necessarily obvious; however, the inventors of the present disclosure presume the reason as follows. Silver particles (produced by a liquid phase (wet type) reduction method using a reducing agent) as the component (A) usually have the surface coated with a surface treatment agent (lubricant). Here, it is speculated that when the mixing temperature of the mixing step is 50° C. or higher, the surface treatment agent covering the silver particles is dissociated (being in a reduced state), and the silver surface is likely to be exposed. Further, since such silver particles with the exposed silver surface are likely to come into direct contact with each other, it is speculated that when the silver particles are heated under the conditions that cure the original sheet of the die-bonding film (or the die-bonding film), the silver particles are sintered together and easily form a sintered body of the silver particles. Thereby, it is conceived that the original sheet of the die-bonding film (or the die-bonding film) includes a sintered body of silver particles in the C-stage state. Note that, silver particles produced by an atomization method are covered with a silver oxide film on the surface of the silver particles due to the characteristics of the production method therefor. According to studies of the inventors of the present disclosure, it was confirmed that in the case of using silver particles produced by an atomization method, even when the mixing temperature of the mixing step is 50° C. or higher, the original sheet of the die-bonding film (or the die-bonding film) to be obtained is less likely to include a sintered body of silver particles in the C-stage state. The mixing temperature of the mixing step may be 55° C. or higher, 60° C. or higher, 65° C. or higher, or 70° C. or higher. The upper limit of the mixing temperature of the mixing step may be, for example, 120° C. or lower, 100° C. or lower, or 80° C. or lower. The mixing time of the mixing step may be, for example, 1 minute or more, 5 minutes or more, or 10 minutes or more, and may be 60 minutes or less, 40 minutes or less, or 20 minutes or less.

The component (B), the component (C), the component (D), the component (E), the component (F), or other components can be added in any stage according to the properties of each component, so that an adhesive varnish containing these components can be obtained. These components may be added, for example, to the raw material varnish before mixing in the mixing step, or may be added to the raw material varnish after mixing in the mixing step. It is preferable that the component (E) and the component (F) are added to the raw material varnish after mixing in the mixing step to obtain an adhesive varnish containing the component (E) and the component (F). In the case of adding these components to the raw material varnish after mixing in the mixing step, these components may be mixed after addition, for example, under the temperature condition of lower than 50° C. (for example, room temperature (25° C.)). The conditions in this case may be 0.1 to 48 hours at room temperature (25° C.).

In an embodiment, the mixing step may be a step of a raw material varnish containing the component (A), the component (B), the component (C), the component (D), and an organic solvent preferably at a mixing temperature of 50° C. or higher to prepare an adhesive varnish containing the component (A), the component (B), the component (C), the component (D), and the organic solvent.

In this way, an adhesive varnish containing the component (A), the organic solvent, and as necessary, the component (B) and the component (C) can be prepared. Regarding the adhesive varnish, air bubbles in the varnish may be removed by vacuum deaeration or the like.

The solid component concentration in the adhesive varnish may be 10 to 80% by mass based on the total amount of the adhesive varnish.

### (Forming Step)

The forming step is a step of forming an original sheet of the die-bonding film using the adhesive varnish. Examples of a method for forming an original sheet of the die-bonding film include a method of applying the adhesive varnish to a support film.

As the method of applying the adhesive varnish to the support film, known methods can be used, and examples thereof include a knife coating method, a roll coating method, a spray coating method, a gravure coating method, a bar coating method, and a curtain coating method.

The adhesive varnish may be applied to a support film, and then the organic solvent may be dried by heating as necessary. Heat drying is not particularly limited as long as it is carried out under the condition in which the organic solvent used is sufficiently volatilized; however, for example, the heat drying temperature may be 50 to 200° C. and the heat drying time may be 0.1 to 30 minutes. Heat drying may be carried out in a stepwise manner at different heat drying temperatures or heat drying times.

In this way, the original sheet of the die-bonding film can be obtained. The thickness of the original sheet of the die-bonding film (or the die-bonding film) can be appropriately adjusted according to the use application, and may be, for example, 3 μm or more, 5 μm or more, or 10 μm or more, or may be 200 μm or less, 100 μm or less, 50 μm or less, or 30 μm or less.

In the B-stage state, the storage elastic modulus of the original sheet of the die-bonding film (die-bonding film D) at 25° C. may be 200 MPa or more. When the storage elastic modulus is 200 MPa or more, there is a tendency that occurrence of defects in the wafer lamination step can be suppressed. The storage elastic modulus may be 300 MPa or more, 400 MPa or more, 500 MPa or more, 600 MPa or more, 800 MPa or more, 1000 MPa or more, 1200 MPa or more, or 1500 MPa or more. The upper limit of the storage elastic modulus of the original sheet of the die-bonding film (die-bonding film D) in the B-stage state at 25° C. is not particularly limited, and may be 3000 MPa or less. Note that, in the present specification, the storage elastic modulus means a value as calculated by a method described in Examples.

In the C-stage state, the thermal conductivity (25° C.±1° C.) of the original sheet of the die-bonding film (die-bonding film D) may be 1.5 W/m·K or more. When the thermal conductivity is 1.5 W/m-K or more, there is a tendency that the heat dissipation properties of the semiconductor device are more excellent. The thermal conductivity may be 2.0 W/m·K or more, 2.5 W/m·K or more, 3.0 W/m·K or more, 3.5 W/m·K or more, 4.0 W/m-K or more, 4.5 W/m·K or more, or 5.0 W/m·K or more. The upper limit of the thermal conductivity (25° C.±1° C.) of the original sheet of the die-bonding film (die-bonding film D) in the C-stage state is not particularly limited, and may be 30 W/m·K or less. Note that, in the present specification, the thermal conductivity means a value as calculated by a method described in Examples. Furthermore, the conditions for curing the original sheet of the die-bonding film (die-bonding film D) to bring it into the C-stage state can be, for example, a heating temperature of 170° C. and a heating time of 3 hours.

The die-bonding film D may be obtained by die cutting (for example, which may also be referred to as “(pre) cutting”, “slicing”, or “dividing”) the original sheet of the die-bonding film, for example, by a punching blade or the like. The shape of the die-bonding film D in plan view may be, for example, circular as illustrated in FIG. 1(a), or may be rectangular (square or oblong). In a case where the shape of the die-bonding film D in plan view is circular, the diameter of the die-bonding film D may be, for example, 290 to 340 mm or 310 to 335 mm.

Examples of the second base material layer 2a in the dicing film 2 include plastic films such as a polytetrafluoroethylene film, a polyethylene terephthalate film, a polyethylene film, a polypropylene film, a polymethylpentene film, and a polyimide film. Furthermore, as necessary, a surface treatment such as a primer application, a UV treatment, a corona discharge treatment, a polishing treatment, and an etching treatment may be performed on the second base material layer 2a.

The pressure-sensitive adhesive layer 2b in the dicing film 2 is not particularly limited as long as it has a sufficient pressure-sensitive adhesive force not to allow scattering of semiconductor chips at the time of dicing and a low pressure-sensitive adhesive force to the extent that semiconductor chips are not damaged in the subsequent step of a pickup step of the semiconductor chips, and a pressure-sensitive adhesive layer conventionally known in the field of dicing films can be used. The pressure-sensitive adhesive layer 2b may be a pressure-sensitive adhesive layer composed of non-ultraviolet curable pressure-sensitive adhesive (non-ultraviolet curable pressure-sensitive adhesive layer), or may be an adhesive layer composed of an ultraviolet curable pressure-sensitive adhesive (ultraviolet curable pressure-sensitive adhesive layer). In a case where the pressure-sensitive adhesive layer 2b is an ultraviolet curable pressure-sensitive adhesive layer, the adhesion of the pressure-sensitive adhesive layer 2b can be lowered by irradiating the pressure-sensitive adhesive layer 2b with ultraviolet rays.

The thickness of the dicing film 2 (the second base material layer 2a and the pressure-sensitive adhesive layer 2b) may be 60 to 150 μm or 70 to 130 μm from the viewpoint of economic efficiency and handling property of the film.

The dicing film 2 may be obtained by die cutting (for example, which may also be referred to as “(pre) cutting”, “slicing”, or “dividing”) the original sheet of the dicing film, for example, by a punching blade or the like. It is preferable that the size of the dicing film 2 in plan view is the same as that of the die-bonding film D, or is larger than that of the die-bonding film D. The shape of the dicing film 2 in plan view may be, for example, circular as illustrated in FIG. 1(a) or may be rectangular (square or oblong), similar to the shape of the die-bonding film D in plan view. In a case where the shape of the dicing film 2 in plan view is circular, the diameter of the dicing film 2 may be, for example, 290 to 500 mm or 310 to 400 mm.

A maximum value of 30° peeling strength of the die-bonding film D with respect to the first base material layer 1 as measured at 25° C. is 0.50 N/20 mm or less. The 30° peeling strength is measured by fixing a dicing film side of a measurement sample (a sample cut into a width of 20 mm×a length of 100 mm from an integrated dicing/die bonding film) to a metal support plate, and peeling the first base material layer at 25° C. under the conditions of a peeling angle of 30° and a peeling rate of 60 mm/min. The maximum value of 30° peeling strength means the maximum value in N=4. The maximum value of 30° peeling strength of the die-bonding film D with respect to the first base material layer 1 as measured at 25° C. may be, for example, 0.45 N/20 mm or less, 0.40 N/20 mm or less, 0.35 N/20 mm or less, or 0.30 N/20 mm or less. The lower limit of the maximum value of 30° peeling strength of the die-bonding film D with respect to the first base material layer 1 may be such a degree that peeling does not occur during transportation, and may be, for example, 0.10 N/20 mm or more.

The maximum value of 30° peeling strength of the die-bonding film D with respect to the first base material layer 1 as measured at 25° C. can be reduced, for example, by reducing the ratio of the depth dv of the cut portion V in the first base material layer 1, or by increasing the ratio of an epoxy resin that is difficult to wet into the first base material layer 1 at 25° C. (that is, a solid epoxy resin having a softening point of 50° C. or higher).

### [Method for Producing Integrated Dicing/Die Bonding Film]

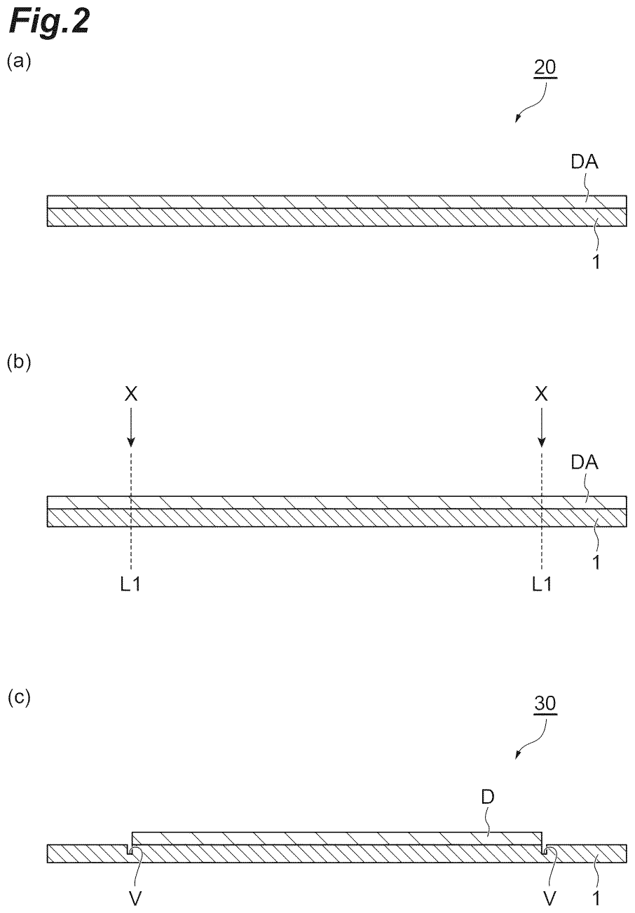

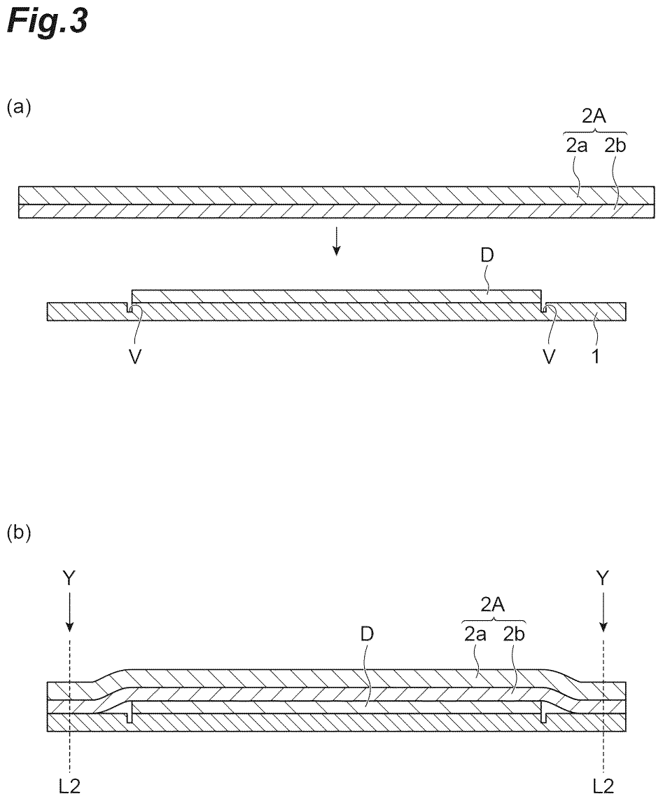

FIGS. 2(a), 2(b), and 2(c) and FIGS. 3(a) and 3(b) are cross-sectional views schematically illustrating production processes of the integrated dicing/die bonding film. A method for producing the integrated film 10 includes preparing a first laminate 20 including the first base material layer 1 and an original sheet DA of the die-bonding film provided on the first base material layer (first step), producing a second laminate 30 including the first base material layer 1 and the die-bonding film D provided on the first base material layer 1 by die cutting the original sheet DA of the die-bonding film in the first laminate 20 so as to form the cut portion V (first cut portion) on a surface of the first base material layer 1 (second step), and laminating the pressure-sensitive adhesive layer 2b and the second base material layer 2a in this order on the die-bonding film D in the second laminate 30 (third step).

### (First Step)

The present step is a step of preparing the first laminate 20. A method for producing the first laminate 20 is not particularly limited as long as a laminate with this configuration is obtainable, but the first laminate 20 can be obtained by sticking the first base material layer 1 and the original sheet DA of the above-described die-bonding film together, or can also be obtained by applying the above-described adhesive varnish onto the first base material layer 1 to form the original sheet DA of the die-bonding film.

### (Second Step)

The present step is a step of producing the second laminate 30. Here, the original sheet DA of the produced first laminate 20 is cut in a direction X from the upper surface of the original sheet DA of the die-bonding film at position L1 by using a punching blade or the like and die-cut ((pre) cut, sliced, or divided) into a desired shape (for example, a circle), so that the second laminate 30 including the die-bonding film D can be produced (see FIGS. 2(b) and 2(c), first precut processing). When the original sheet DA of the die-bonding film is die-cut into a desired shape, the cut portion V (first cut portion) is formed on the surface of the first base material layer 1 along the outer edge of the desired shape of the die-cut die-bonding film (see FIG. 2(c)). In this way, the second laminate 30 including a first base material layer 1 and a die-bonding film D provided on the first base material layer 1 can be produced.

### (Third Step)

The present step is a step of laminating the pressure-sensitive adhesive layer 2b and the second base material layer 2a in this order on the die-bonding film D in the second laminate 30 (see FIGS. 3(a) and 3(b)). Examples of the method of laminating the pressure-sensitive adhesive layer 2b and the second base material layer 2a in this order include a method in which an original sheet 2A of the dicing film having the second base material layer 2a and the pressure-sensitive adhesive layer 2b provided on the second base material layer 2a is disposed to cover the entire surface of the die-bonding film D, and the original sheet 2A of the dicing film thus disposed is cut in a direction Y from the upper surface of the original sheet of the dicing film at position L2 by using a punching blade or the like and die-cut ((pre) cut, sliced, or divided) to have a desired shape (for example, a circular) (see FIG. 3(b), second precut processing).

When the original sheet 2A of the dicing film is die-cut into a desired shape (for example, a circle), a cut portion (second cut portion) may be formed on the surface of the first base material layer 1 along the outer edge of the desired shape of the die-cut dicing film 2. The depth of the second cut portion may be, for example, less than the thickness of the first base material layer 1.

Through the first step, the second step, and the third step as described above, the integrated film 10 can be obtained.

### [Method for Producing a Semiconductor Device]

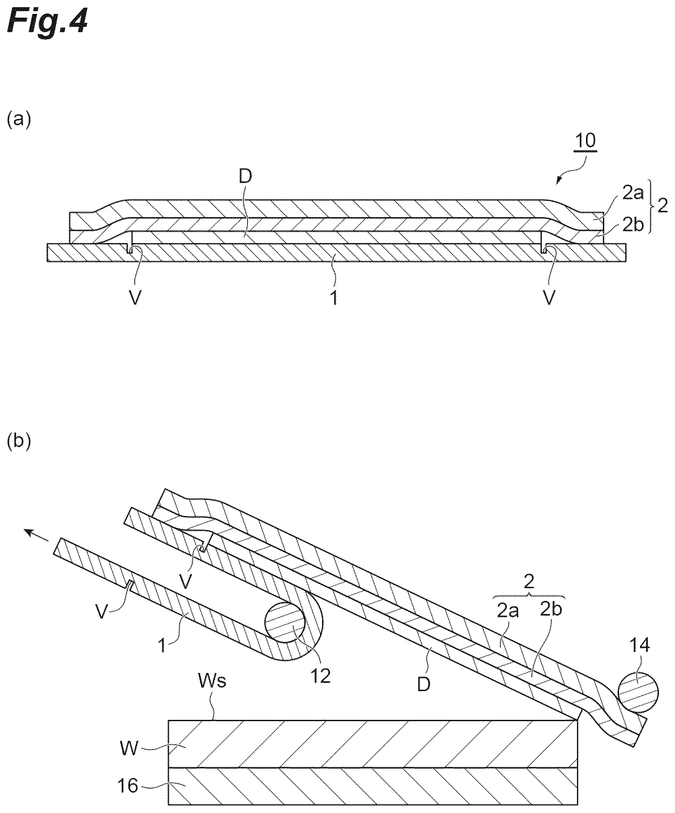

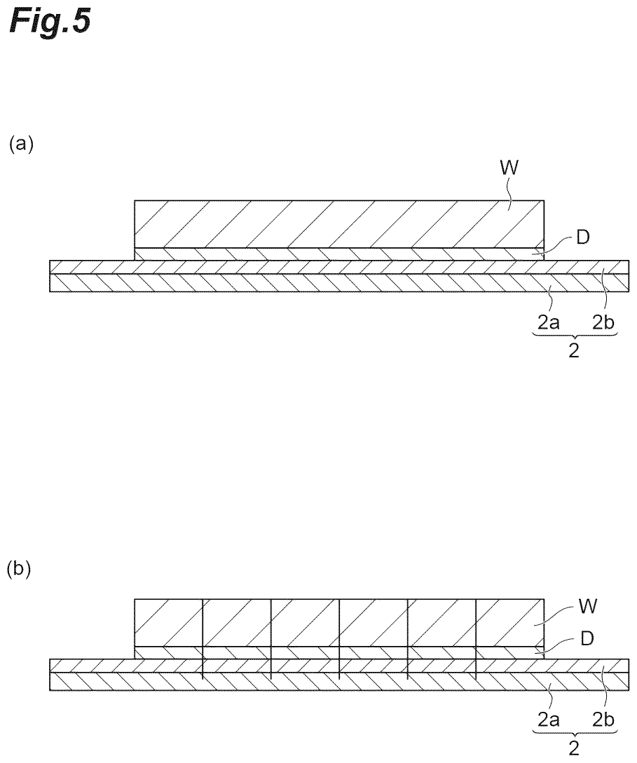

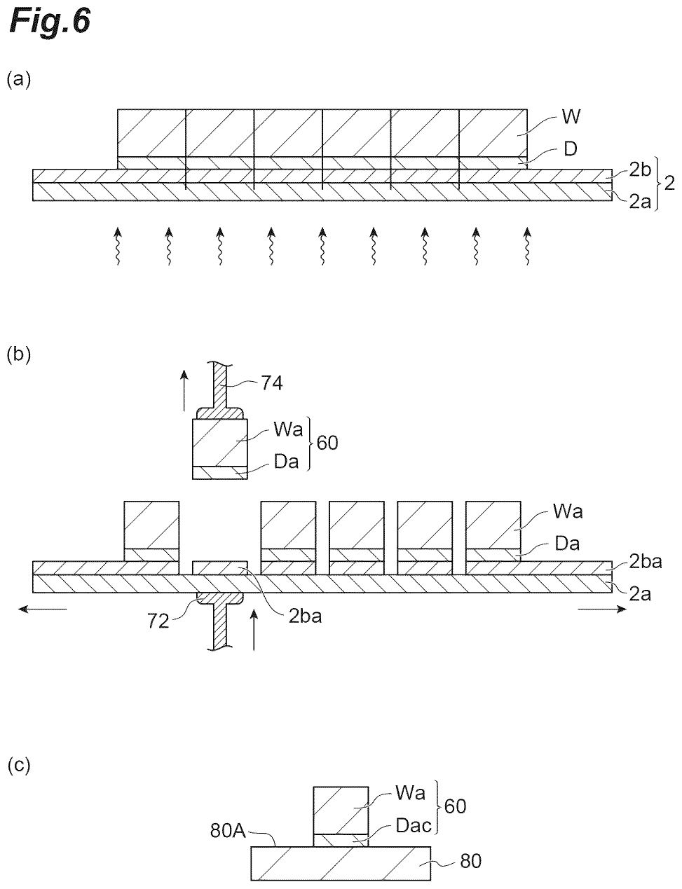

FIGS. 4, 5, and 6 are schematic cross-sectional views illustrating an embodiment of a method for producing a semiconductor device. FIGS. 4(a) and 4(b) are cross-sectional views schematically illustrating respective steps of a method for producing a semiconductor device. FIGS. 5(a) and 5(b) are cross-sectional views schematically illustrating respective steps of a method for producing a semiconductor device. FIGS. 6(a), 6(b), and 6(c) are cross-sectional views schematically illustrating respective steps of a method for producing a semiconductor device. The method for producing a semiconductor device includes peeling the first base material layer 1 of the above-described integrated film 10 and sticking the die-bonding film D of the integrated film 10 to a semiconductor wafer W (wafer lamination step, see FIGS. 4(a) and 4(b)), producing a plurality of singulated die-bonding film piece-attached semiconductor chips 60 by dicing the semiconductor wafer W with the die-bonding film D stuck thereto (dicing step, see FIG. 5(b)), and bonding the die-bonding film piece-attached semiconductor chips 60 to a support member 80 with a die-bonding film piece Da interposed therebetween (semiconductor chip bonding step, see FIG. 6(c)). The method for producing a semiconductor device may further include, as necessary, irradiating the pressure-sensitive adhesive layer 2b with ultraviolet rays (through the second base material layer 2a) (ultraviolet irradiation step, see FIG. 6(a)), picking up a semiconductor chip Wa with a die-bonding film piece Da attached thereto (die-bonding film piece-attached semiconductor chip 60) from a pressure-sensitive adhesive layer 2ba (pickup step, see FIG. 6(b)), and thermally curing the die-bonding film piece Da in the die-bonding film piece-attached semiconductor chip 60 bonded to the support member 80 (thermal curing step), between the dicing step and the semiconductor chip bonding step.

### (Wafer Lamination Step)

In the present step, the first base material layer 1 of the integrated film 10 is peeled, and the die-bonding film D of the integrated film 10 is stuck to the semiconductor wafer W (see FIGS. 4(a) and 4(b)). First, the integrated film 10 is prepared (see FIG. 4(a)). Subsequently, by pulling the first base material layer 1, the die-bonding film D of the integrated film 10 is stuck to a surface Ws of the semiconductor wafer W, for example, using a member for sticking 14 while the first base material layer 1 is peeled from the die-bonding film D of the integrated film 10, for example, using a member for peeling 12 and the semiconductor wafer W is heated by a wafer mounter 16 (see FIG. 4(b)). The heating temperature of the semiconductor wafer W may be usually 70° C. or higher.

Such a series of sticking operations can be performed continuously in an automated process, and examples of a device performing such a sticking operation include a wafer mount device (RAD-2500 manufactured by LINTEC Corporation).

In the wafer lamination step, there are cases where defects occur, for example, the first base material layer 1 and the die-bonding film D of the integrated film 10 cannot be peeled from each other, the die-bonding film is pulled by the first base material layer to be torn off, and even when these members can be peeled midway, the die-bonding film is in a stretched state and cannot be mounted on the semiconductor wafer. According to the integrated film 10 of the present embodiment, occurrence of such defects can be suppressed.

Examples of the semiconductor wafer W include single crystal silicon, polycrystal silicon, various ceramics, and compound semiconductors such as gallium arsenide. A circuit surface of the semiconductor wafer W may be provided on a surface opposite to the surface Ws.

In this way, a laminate including the dicing film 2 (the second base material layer 2a and the pressure-sensitive adhesive layer 2b), the die-bonding film D, and the semiconductor wafer W in this order can be obtained (see FIG. 5(a)).

### (Dicing Step)

In the present step, the semiconductor wafer W and the die-bonding film D are diced to be singulated (see FIG. 5(b)). At this time, a part of the pressure-sensitive adhesive layer 2b, or the entirety of the pressure-sensitive adhesive layer 2b and a part of the second base material layer 2a may be diced to be singulated. As a dicing method in the dicing step, a known dicing method can be used. In this way, the integrated film 10 also functions as a dicing film.

### (Ultraviolet Irradiation Step)

In a case where the pressure-sensitive adhesive layer 2b is an ultraviolet curable pressure-sensitive adhesive layer, the method for producing a semiconductor device may include an ultraviolet irradiation step. In the present step, the pressure-sensitive adhesive layer 2b is irradiated with ultraviolet rays (through the second base material layer 2a) (see FIG. 6(a)). In the ultraviolet irradiation, the wavelength of the ultraviolet rays may be 200 to 400 nm. Regarding the ultraviolet irradiation conditions, the illumination and the amount of irradiation may be in a range of 30 to 240 mW/cm² and a range of 50 to 500 m·J/cm², respectively.

### (Pickup Step)

In the present step, while the singulated die-bonding film piece-attached semiconductor chips 60 are separated apart from each other by expanding the second base material layer 2a, the die-bonding film piece-attached semiconductor chips 60 that have been thrusted up by a needle 72 from the second base material layer 2a side are sucked by a suction collet 74 and picked up from the pressure-sensitive adhesive layer 2ba (see FIG. 6(b)). Note that, the die-bonding film piece-attached semiconductor chip 60 has a semiconductor chip Wa and a die-bonding film piece Da. The semiconductor chip Wa is obtained by singulating the semiconductor wafer W, and the die-bonding film piece Da is obtained by singulating the die-bonding film D. Furthermore, the pressure-sensitive adhesive layer 2ba is obtained by singulating the pressure-sensitive adhesive layer 2b. The pressure-sensitive adhesive layer 2ba may remain on the second base material layer 2a after the die-bonding film piece-attached semiconductor chip 60 is picked up. In the present step, it is not necessary to expand the second base material layer 2a, but by expanding the second base material layer 2a, pickup property can be further improved.

The thrust-up amount by the needle 72 can be appropriately set. Further, from the viewpoint of securing sufficient pickup property even with respect to an extremely thin wafer, for example, two-stage or three-stage thrust-up may be performed. Furthermore, the die-bonding film piece-attached semiconductor chip 60 may be picked up by a method other than the method using the suction collet 74.

### (Semiconductor Chip Bonding Step)

In the present step, the die-bonding film piece-attached semiconductor chip 60 thus picked up is bonded to the support member 80 by thermocompression bonding with the die-bonding film piece Da interposed therebetween (see FIG. 6(c)). A plurality of die-bonding film piece-attached semiconductor chips 60 may be bonded to the support member 80.

The heating temperature in thermocompression bonding may be, for example, 80 to 160° C. The load in thermocompression bonding may be, for example, 5 to 15 N. The heating time in thermocompression bonding may be, for example, 0.5 to 20 seconds.

### (Thermal Curing Step)

In the present step, the die-bonding film piece Da in the die-bonding film piece-attached semiconductor chip 60 bonded to the support member 80 is thermally cured. By (further) thermally curing the die-bonding film piece Da bonding the semiconductor chip Wa and the support member 80 or a cured product Dac of the die-bonding film piece, stronger adhesive fixation is enabled. Furthermore, in a case where the component (A) is silver particles (preferably, silver particles produced by a reduction method), there is a tendency that a sintered body of the silver particles is even more easily obtained by (further) thermally curing the die-bonding film piece Da or the cured product Dac of the die-bonding film piece. In the case of performing thermal curing, curing may be performed by simultaneously applying pressure. The heating temperature in the present step can be appropriately changed depending on the constituent components of the die-bonding film piece Da. The heating temperature may be, for example, 60 to 200° C., and may be 90 to 190° C. or 120 to 180° C. The heating time may be 30 minutes to 5 hours, or may be 1 to 3 hours or 2 to 3 hours. Note that, heating may be performed while changing the temperature or pressure stepwise.

The die-bonding film piece Da may become the cured product Dac of the die-bonding film piece by being cured through the semiconductor chip bonding step or the thermal curing step. In a case where the component (A) is silver particles (preferably, silver particles produced by a reduction method), the cured product Dac of the die-bonding film piece may include a sintered body of the silver particles. Therefore, the semiconductor device thus obtained may have excellent heat dissipation properties.

The method for producing a semiconductor device may include, as necessary, electrically connecting a tip of a terminal part (inner lead) of the support member and an electrode pad on a semiconductor chip by using a bonding wire (wire bonding step). As the bonding wire, for example, a gold wire, an aluminum wire, a copper wire, and the like are used. The temperature at the time of performing wire bonding may be in a range of 80 to 250° C. or 80 to 220° C. The heating time may be several seconds to several minutes. Wire bonding may be performed in a state of being heated within the above-described temperature range, by using the vibration energy of ultrasonic waves and the pressure-bonding energy of applied pressure in combination.

The method for producing a semiconductor device may include, as necessary, encapsulating semiconductor chips by a sealing material (encapsulating step). The present step is performed in order to protect the semiconductor chips or bonding wires mounted on the support member. The present step can be performed by molding a resin for encapsulation (encapsulation resin) in a mold. The encapsulation resin may be, for example, an epoxy-based resin. Due to the heat and pressure during encapsulation, the support member and residue are embedded, and detachment caused by air bubbles at the adhesive interface can be prevented.

The method for producing a semiconductor device may include, as necessary, completely curing the encapsulation resin that is insufficiently cured in the encapsulating step (post-curing step). Even in a case where the die-bonding film piece is not thermally cured in the encapsulating step, the die-bonding film piece is thermally cured together with curing of the encapsulation resin to enable adhesive fixation in the present step. The heating temperature in the present step can be appropriately set according to the type of the encapsulation resin, and for example, the heating temperature may be in a range of 165 to 185° C., and the heating time may be about 0.5 to 8 hours.

The method for producing a semiconductor device may include, as necessary, heating the die-bonding film piece-attached semiconductor chip bonded to the support member by using a reflow furnace (heat melting step). In the present step, the resin-encapsulated semiconductor device may be surface-mounted on a support member. Examples of the method for surface mounting include reflow soldering of supplying solder in advance onto a printed circuit board, and then heat melting solder by means of hot air or the like to perform soldering. Examples of the heating method include hot air reflow and infrared reflow. Furthermore, the heating method may be a method of heating the entirety or may be a method of locally heating. The heating temperature may be, for example, within a range of 240 to 280° C.

### [Semiconductor Device]

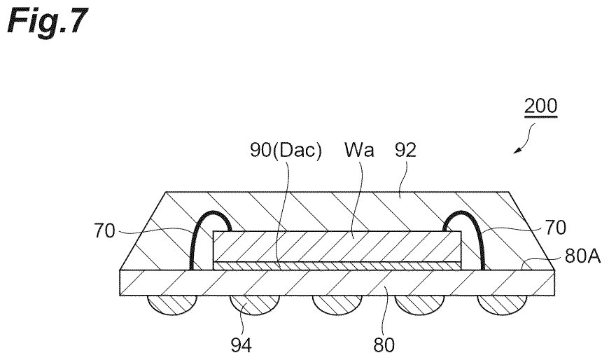

FIG. 7 is a schematic cross-sectional view illustrating an embodiment of a semiconductor device. A semiconductor device 200 illustrated in FIG. 7 includes a semiconductor chip Wa, a support member 80 having the semiconductor chip Wa mounted thereon, and a bonding adhesive member 90. The bonding adhesive member 90 is provided between the semiconductor chip Wa and the support member 80, and bonds the semiconductor chip Wa and the support member 80 together. The bonding adhesive member 90 is a cured product of the die-bonding film (a cured product 10ac of the die-bonding film piece). A connection terminal (not illustrated) of the semiconductor chip Wa may be electrically connected to an external connection terminal (not illustrated) by means of a wire 70. The semiconductor chip Wa may be encapsulated by using a sealing material layer 92 formed from a sealing material. On a surface of the support member 80 opposite to a surface 80A, a solder ball 94 may be formed for electrical connection with an external substrate (motherboard) (not illustrated).

The semiconductor chip Wa (semiconductor element) may be, for example, an IC (integrated circuit) or the like. Examples of the support member 80 include lead frames such as an Alloy 42 lead frame and a copper lead frame; plastic films such as a polyimide resin and an epoxy resin; modified plastic films obtained by impregnating a base material such as a glass nonwoven fabric with a plastic such as a polyimide resin or an epoxy resin and curing the plastic; and ceramics such as alumina. The thickness of the semiconductor chip Wa is, for example, 10 to 200 μm and may be 20 to 100 μm.

Since the semiconductor device 200 includes a cured product of the above-described die-bonding film as the bonding adhesive member 90, the semiconductor device 200 has excellent heat dissipation properties.

### EXAMPLES

Hereinafter, the present disclosure will be described in detail based on Examples; however, the present disclosure is not limited thereto.

### [Preparation of Adhesive Varnish] (Production Examples 1 to 3)

A raw material varnish was prepared by adding cyclohexanone as an organic solvent to the component (A), the component (B), the component (C), and the component (D) with the reference symbols and composition ratios (unit: parts by mass) shown in Table 1. This raw material varnish was stirred for 20 minutes at a rate of 4000 rotations/min under the mixing temperature condition of 70° C. by using a homo-disper (T.K. HOMO MIXER MARK II manufactured by Tajima-K.K.) to obtain an adhesive varnish. Next, the adhesive varnish was left to stand until the temperature reached 20 to 30° C., the component (E) and the component (F) were then added to the adhesive varnish, and the mixture was stirred overnight at a rate of 250 rotations/min by using a three-one motor. In this way, an adhesive varnish of each of Production Examples 1 to 3 was prepared in which the total content (solid component concentration) of the component (A), the component (B), the component (C), and the component (D) was 61% by mass.

Note that, symbols of respective components in Table 1 mean as follows.

### Component (A): Electroconductive Particles

(A-1) Silver particles AG-3-1F (trade name, manufactured by DOWA Electronics Materials Co., Ltd., shape: spherical, average particle size (laser 50% particle size (D₅₀)): 1.5 μm)

### Component (B): Thermosetting Resin

(B-1) N-500P-10 (trade name, manufactured by DIC Corporation, cresol novolac type epoxy resin, epoxy equivalent: 204 g/eq, softening point: 84° C., solid at 25° C.)
(B-2) EXA-830CRP (trade name, manufactured by DIC Corporation, bisphenol F type epoxy resin, epoxy equivalent: 159 g/eq, liquid at 25° C.)

### Component (C): Curing Agent

(C-1) MEH-7800M (trade name, manufactured by Meiwa Plastic Industries, Ltd., phenyl aralkyl type phenolic resin, hydroxyl equivalent: 174 g/eq, softening point: 80° C.)

### Component (D): Elastomer

(D-1) SG-P3 (trade name, manufactured by Nagase ChemteX Corporation, acrylic rubber, weight average molecular weight: 800000, Tg: −7° C.)

### Component (E): Coupling Agent

(E-1) A-1160 (trade name, manufactured by Nippon Unicar Company Limited, γ-ureidopropyltriethoxysilane)

### Component (F): Curing Accelerator

(F-1) 2PZ-CN (trade name, manufactured by SHIKOKU CHEMICALS CORPORATION, 1-cyanoethyl-2-phenylimidazole)

TABLE 1

| | | | Production | Production | Production |
|---|---|---|---|---|---|
| | | | Example 1 | Example 2 | Example 3 |
| (A) | (A-1) | % by mass | 78.0 | 76.0 | 76.0 |
| (B) | (B-1) | % by mass | 3.1 | 4.9 | 3.9 |
| | (B-2) | % by mass | 6.2 | 4.9 | 5.8 |
| (C) | (C-1) | % by mass | 7.7 | 7.8 | 7.9 |
| (D) | (D-1) | % by mass | 5.0 | 6.4 | 6.4 |
| (E) | (E-1) | % by mass | 0.025 | 0.025 | 0.025 |
| (F) | (F-1) | % by mass | 0.005 | 0.005 | 0.005 |

### [Production of Integrated Dicing/Die Bonding Film] (Example 1)

### <Production of First Laminate>

The first laminate including a first base material layer and an original sheet of the die-bonding film provided on the first base material layer was produced by using the adhesive varnish of Production Example 1. Each adhesive varnish was subjected to vacuum degassing, and the adhesive varnish obtained thereafter was applied onto a polyethylene terephthalate (PET) film (thickness: 38 μm) subjected to a mold release treatment as the first base material layer. The applied adhesive varnish was dried by heating in two stages for 5 minutes at 90° C. and subsequently for 5 minutes at 130° C., and thus, the first laminate including an original sheet of the die-bonding film having a thickness of 25 μm in a B-stage state was obtained on the PET film.

### <Measurement of Storage Elastic Modulus of Die-Bonding Film>

The storage elastic modulus at 25° C. of (the original sheet of) the produced die-bonding film was measured by using a dynamic Viscoelasticity measuring apparatus (Rheogel E-4000 manufactured by UBM KK). More specifically, a plurality of die-bonding films each having a thickness of 25 μm were laminated to have a thickness of about 200 μm, and this product was cut into 4 mm (width)×30 mm (length) to produce measurement samples. The produced samples were measured in a temperature range of −20 to 80° C. under the conditions of a frequency of 10 Hz and a temperature increase rate of 3° C./min, and a value of the storage elastic modulus at 25° C. was regarded as the storage elastic modulus at 25° C. Results are shown in Table 2.

### <Production of Second Laminate>

In the obtained first laminate of Example 1, the cutting depth in the first base material layer was adjusted to 15 μm or less, and the original sheet of the die-bonding film was subjected to circular die cutting processing (first precut processing) of $335 mm. Thereafter, by removing unnecessary portions of the original sheet of the die-bonding film, a second laminate including a first base material layer and a die-bonding film provided on the first base material layer was obtained. In the second laminate, the first base material layer has a cut portion (first cut portion) provided on the surface of the die-bonding film side along the outer edge of the die-bonding film. The depth of the first cut portion by cross-sectional observation with an electron microscope was 13.0 μm, and the ratio of the depth of the first cut portion with respect to the thickness of the first base material layer was 34.2%.

### <Production of Integrated Dicing/Die Bonding Film>

An original sheet of the dicing film having a non-ultraviolet curable pressure-sensitive adhesive layer (thickness of the second base material layer: 80 μm, thickness of the pressure-sensitive adhesive layer: 30 μm) was prepared, and the non-ultraviolet curable pressure-sensitive adhesive layer side of the original sheet of the dicing film was disposed on the die-bonding film in the second laminate obtained above and stuck under the conditions of 25° C., a linear pressure of 1 kg/cm, and a speed of 0.5 m/min. Next, the cutting depth in the first base material layer was adjusted to 15 μm or less, the original sheet of the dicing film was subjected to circular die cutting processing (second precut processing) of $370 mm concentrically with the die-bonding film to produce an integrated dicing/die bonding film of Example 1.

### Example 2

A first laminate, a second laminate, and an integrated dicing/die bonding film of Example 2 were produced in the same manner as in Example 1, except that the adhesive varnish of Production Example 2 was used instead of the adhesive varnish of Production Example 1. In the second laminate, the depth of the first cut portion by cross-sectional observation with an electron microscope was 13.1 μm, and the ratio of the depth of the first cut portion with respect to the thickness of the first base material layer was 34.5%.

### Example 3

A first laminate, a second laminate, and an integrated dicing/die bonding film of Example 3 were produced in the same manner as in Example 1, except that the adhesive varnish of Production Example 3 was used instead of the adhesive varnish of Production Example 1. In the second laminate, the depth of the first cut portion by cross-sectional observation with an electron microscope was 12.9 μm, and the ratio of the depth of the first cut portion with respect to the thickness of the first base material layer was 34.0%.

### Comparative Example 1

A first laminate, a second laminate, and an integrated dicing/die bonding film of Comparative Example 1 were produced in the same manner as in Example 1, except that the cutting depth in the first base material layer was adjusted to be deeper than in Example 1. In the second laminate, the depth of the first cut portion by cross-sectional observation with an electron microscope was 20.1 μm, and the ratio of the depth of the first cut portion with respect to the thickness of the first base material layer was 53.0%.

### [Evaluation of Integrated Dicing/Die Bonding Film]

(Measurement of Maximum Value of 30° Peeling Strength of Die-Bonding Film with Respect to First Base Material Layer)

The integrated dicing/die bonding films of Examples 1 to 3 and Comparative Example 1 were used. Each of the integrated dicing/die bonding films was cut into a width of 20 mm×a length of 100 mm, and then used as a measurement sample. The dicing film side of the measurement sample was fixed to a metal support plate, the 30° peeling strength was measured by peeling the first base material layer under the conditions of a peeling angle of 30° and a peeling rate of 60 mm/min in this state, and the maximum value in N=4 was determined. Note that, the storage of the sample and the measurement of the peeling strength were performed in an environment of a temperature of 25° C. and a relative humidity of 40%. Results are shown in Table 2.

### (Wafer Lamination Test)

The rate of occurrence of defects in the wafer lamination step was evaluated in a wafer lamination test. First, a plurality of integrated dicing/die bonding films of each of Examples 1 to 3 and Comparative Example 1 were prepared. Subsequently, a wafer lamination test was performed by using a wafer mount device (RAD-2500 manufactured by LINTEC Corporation). At this time, the wafer size was set to a size of ϕ8 inches (203 mm) and a thickness of 150 μm, and the lamination speed was set to 35 mm/sec. The temperature of the wafer mounter was set to 70° C. For the evaluation, the wafer lamination test was performed 15 times to determine the ratio of occurrence of defects. Results are shown in Table 2.

TABLE 2

| | | | | Comparative |
|---|---|---|---|---|
| | Example 1 | Example 2 | Example 3 | Example 1 |
| Type of adhesive varnish | Production | Production | Production | Production |
| | Example 1 | Example 2 | Example 3 | Example 1 |
| storage elastic modulus of die-bonding film (MPa @25° C.) | 250 | 1540 | 600 | 250 |
| Ratio (%) of depth of first cut portion with respect to | 34.2 | 34.5 | 34.0 | 53.0 |
| thickness of first base material layer | (13.0/38.0) | (13.1/38.0) | (12.9/38.0) | (20.1/38.0) |
| Maximum value of 30° peeling strength (N/20 mm @25° C.) | 0.49 | 0.20 | 0.26 | 0.70 |
| Ratio of occurrence of defects | 1/15 | 0/15 | 0/15 | 7/15 |

As shown in Table 2, the integrated dicing/die bonding films of Examples 1 to 3 in which the maximum value of 30° peeling strength of the die-bonding film with respect to the first base material layer was 0.5 N/20 mm or less had an extremely low occurrence of defects as compared to the integrated dicing/die bonding film of Comparative Example 1 in which this maximum value of 30° peeling strength was more than 0.5 N/20 mm. From these results, it is confirmed that the integrated dicing/die bonding film, which includes, in the stated order, a first base material layer, a die-bonding film containing electroconductive particles, a pressure-sensitive adhesive layer, and a second base material layer, of the present disclosure can suppress occurrence of defects in the wafer lamination step.

### REFERENCE SIGNS LIST

1: first base material layer, 2: dicing film, 2a: second base material layer, 2b, 2ba: pressure-sensitive adhesive layer, 2A: original sheet of dicing film, 10: integrated dicing/die bonding film, 12: member for peeling, 14: member for sticking, 16: wafer mounter, 20: first laminate, 30: second laminate, 60: die-bonding film piece-attached semiconductor chip, 70: wire, 72: needle, 74: suction collet, 80: support member, 92: sealing material layer, 94: solder ball, 200: semiconductor device, D: die-bonding film, DA: original sheet of die-bonding film, Da: die-bonding film piece, Dac: cured product of die-bonding film piece, V: cut portion, W: semiconductor wafer, Wa: semiconductor chip.

1. An integrated dicing/die bonding film comprising, in the stated order: a first base material layer; a die-bonding film comprising electroconductive particles; a pressure-sensitive adhesive layer; and a second base material layer, wherein
the first base material layer has a cut portion provided on a surface of the die-bonding film side along an outer edge of the die-bonding film, and
a maximum value of 30° peeling strength of the die-bonding film with respect to the first base material layer as measured at 25° C. is 0.50 N/20 mm or less.

2. The integrated dicing/die bonding film according to claim 1, wherein the die-bonding film further comprises a thermosetting resin, a curing agent, and an elastomer, and
a content of the electroconductive particles is 70.0% by mass or more based on the total amount of the die-bonding film.

3. The integrated dicing/die bonding film according to claim 1, wherein an average particle size of the electroconductive particles is 0.01 to 10 μm.

4. The integrated dicing/die bonding film according to claim 1, wherein the electroconductive particles are silver particles.

5. A method for producing the integrated dicing/die bonding film according to any one of claims 1 to 4, the method comprising:
preparing a first laminate including the first base material layer and an original sheet of the die-bonding film provided on the first base material layer;
producing a second laminate including the first base material layer and the die-bonding film provided on the first base material layer by die cutting the original sheet of the die-bonding film in the first laminate so as to form the cut portion on a surface of the first base material layer; and
laminating the pressure-sensitive adhesive layer and the second base material layer in this order on the die-bonding film in the second laminate.

6. A method for producing a semiconductor device, the method comprising:
peeling the first base material layer of the integrated dicing/die bonding film according to any one of claims 1 to 4 and sticking the die-bonding film of the integrated dicing/die bonding film to a semiconductor wafer;
producing a plurality of singulated die-bonding film piece-attached semiconductor chips by dicing the semiconductor wafer with the die-bonding film stuck thereto;
bonding the die-bonding film piece-attached semiconductor chips to a support member with a die-bonding film piece interposed therebetween; and
thermally curing the die-bonding film piece in the die-bonding film piece-attached semiconductor chips bonded to the support member.
